(19) United States
(12) Patent Application Publication
(10) Pub. No.: US 2026/0293438 A1
(43) Pub. Date: Sep. 24, 2026

(54) DISPLAY PANEL, ELECTRONIC APPARATUS INCLUDING THE SAME, AND MANUFACTURING METHOD FOR THE DISPLAY PANEL

(71) Applicants: SAMSUNG DISPLAY CO., LTD., YONGIN-SI (KR); POSTECH RESEARCH AND BUSINESS DEVELOPMENT FOUNDATION, Pohang-si (KR)

(72) Inventors: HYELIM CHOI, Yongin-si (KR); JOON SEOK PARK, Yongin-si (KR); YOONYOUNG CHUNG, Pohang-si (KR); DOWAN KANG, Pohang-si (KR); JUYOUNG YUN, Pohang-si (KR)

(21) Appl. No.: 19/423,073

(22) Filed: Dec. 17, 2025

(30) Foreign Application Priority Data
Mar. 24, 2025 (KR) 10-2025-0037257

(51) Int. Cl. H10K 59/121; H10K 59/12

(52) U.S. Cl. CPC H10K 59/1213; H10K 59/1201

(57) ABSTRACT

A display panel includes a base layer. A light-emitting element layer is disposed on the base layer and includes a light-emitting element. A circuit layer is disposed on the base layer and includes a thin film transistor electrically connected to the light-emitting element. The thin film transistor includes a gate electrode. A channel overlaps the gate electrode and includes an oxide semiconductor. A source electrode is disposed on a first end of the channel. A drain electrode is disposed on an opposite second end of the channel. An insertion layer is disposed between the channel and the source electrode and between the channel and the drain electrode. The insertion layer includes a dipole layer disposed on the channel, and an oxygen diffusion prevention layer disposed on the dipole layer.

### CROSS-REFERENCE TO RELATED APPLICATIONS

This application claims priority under 35 U.S.C. § 119 to Korean Patent Application No. 10-2025-0037257, filed on Mar. 24, 2025 in the Korean Intellectual Property Office, the disclosure of which is incorporated by reference in its entirety herein.

### 1. TECHNICAL FIELD

The present disclosure herein relates to a display panel, an electronic apparatus including the same, and a manufacturing method for a display panel, and more particularly, to a display panel including a thin film transistor, an electronic apparatus including the same, and a manufacturing method for the display panel including the thin film transistor.

### 2. DISCUSSION OF RELATED ART

Various multimedia electronic apparatuses, such as a television, a mobile phone, a tablet computer, a navigation system, and a game console, include an active region that is activated in response to electrical signals. The electronic apparatus may detect pressure applied from the outside, and at the same time, provide information to a user by displaying various images through the active region.

The electronic apparatus may include a light-emitting element having an organic light-emitting material or a quantum-dot light-emitting material, and a pixel circuit for controlling electrical signals applied to the light-emitting element. The pixel circuit may include a thin film transistor. As the channel length of the thin film transistor has been decreasing along with the miniaturization of electronic apparatuses, research is being conducted to reduce contact resistance between the channel and an electrode.

### SUMMARY

The present disclosure provides a display panel including a thin film transistor with reduced contact resistance.

The present disclosure also provides an electronic apparatus including the thin film transistor with reduced contact resistance.

The present disclosure also provides a manufacturing method for the display panel including the thin film transistor with reduced contact resistance.

According to an embodiment of the present inventive concept, a display panel includes a base layer. A light-emitting element layer is disposed on the base layer and includes a light-emitting element. A circuit layer is disposed on the base layer and includes a thin film transistor electrically connected to the light-emitting element. The thin film transistor includes a gate electrode. A channel overlaps the gate electrode and includes an oxide semiconductor. A source electrode is disposed on a first end of the channel. A drain electrode is disposed on an opposite second end of the channel. An insertion layer is disposed between the channel and the source electrode and between the channel and the drain electrode. The insertion layer includes a dipole layer disposed on the channel, and an oxygen diffusion prevention layer disposed on the dipole layer.

In an embodiment, the dipole layer may be directly disposed on the channel, and the dipole layer may include a metal oxide which forms oxygen vacancy in the dipole layer to dope the channel.

In an embodiment, the oxygen diffusion prevention layer may be directly disposed between the dipole layer and the source electrode and between the dipole layer and the drain electrode, and the oxygen diffusion prevention layer may include a metal oxide that blocks oxygen diffusion from the channel to the source electrode and the drain electrode.

In an embodiment, the oxygen diffusion prevention layer may have a thickness that allows electron tunneling.

In an embodiment, the oxygen diffusion prevention layer may have a thickness in a range of less than or equal to about 3 nm.

In an embodiment, the oxygen diffusion prevention layer may have a thickness in a range of less than or equal to about 1 nm.

In an embodiment, the oxygen diffusion prevention layer may include at least one compound selected from Al₂O₃, TiO₂, ZnO, MgO, HfO₂, or a combination thereof.

In an embodiment, the dipole layer may include at least one compound selected from ITO, ZnO, HfZrO, TiO₂. or a combination thereof.

In an embodiment, the channel may include at least one of ITZO, IGZO, TZO, ATZO, ZnO, or a combination thereof.

In an embodiment, the circuit layer may further include a gate insulation film disposed between the gate electrode and the channel.

According to an embodiment of the present inventive concept, an electronic device includes a display module comprising a base layer, a light-emitting element layer disposed on the base layer and comprising a light-emitting element, and a circuit layer disposed on the base layer and comprising a thin film transistor electrically connected to the light-emitting element. A window is disposed on the display module. The thin film transistor includes a gate electrode. A channel overlapping the gate electrode and comprising an oxide semiconductor. A source electrode is disposed on a first end of the channel. A drain electrode is disposed on an opposite second end of the channel. An insertion layer is disposed between the channel and the source electrode and between the channel and the drain electrode. The insertion layer includes a dipole layer disposed on the channel and an oxygen diffusion prevention layer disposed on the dipole layer.

In an embodiment, the dipole layer may include a metal oxide that forms oxygen vacancy in the dipole layer to dope the channel.

In an embodiment, the oxygen diffusion prevention layer may include a metal oxide that blocks oxygen diffusion from the channel to the source electrode and the drain electrode.

In an embodiment, the electronic device may further include at least one of a processor, a memory, or a power module.

In an embodiment, the electronic device may be a television, a monitor, an outdoor billboard, a personal computer, a laptop computer, a personal digital assistant, a car dashboard, a center fascia, a navigation system, a room-mirror display, a game console, a smartphone, a tablet computer, a smart watch, smart glasses, a head-mounted display, or a camera.

According to an embodiment of the present inventive concept, a method of manufacturing a display panel including forming a channel comprising an oxide semiconductor, forming an insertion layer on the channel, forming a source electrode and a drain electrode on the insertion layer. The insertion layer is disposed between the source electrode and the channel and between the drain electrode and the channel. The forming of the insertion layer includes forming a dipole layer on the channel, and forming an oxygen diffusion prevention layer while reducing the dipole layer using a metal precursor with reducibility.

In an embodiment, the insertion layer may be formed through an atomic layer deposition (ALD) process.

In an embodiment, the dipole layer may include a metal oxide that forms oxygen vacancy in the dipole layer to dope the channel.

In an embodiment, the oxygen diffusion prevention layer may include a metal oxide that blocks oxygen diffusion from the channel to the source electrode and the drain electrode.

In an embodiment, the oxygen diffusion prevention layer may be have a thickness that allows for electron tunneling.

### BRIEF DESCRIPTION OF THE DRAWINGS

The accompanying drawings are included to provide a further understanding of non-limiting embodiments of the present inventive concept, and are incorporated in and constitute a part of this specification. The drawings illustrate embodiments of the present inventive concept and, together with the description, serve to explain principles of embodiments of the present inventive concept. In the drawings:

FIG. 1 is a block diagram of an electronic apparatus according to an embodiment of the present inventive concept;

FIG. 2 is a schematic view of various electronic apparatuses according to an embodiment of the present inventive concept;

FIG. 3 is a combined perspective view of an electronic apparatus according to an embodiment of the present inventive concept;

FIG. 4 is an exploded perspective view of an electronic apparatus according to an embodiment of the present inventive concept;

FIG. 5 is a cross-sectional view of an electronic apparatus according to an embodiment of the present inventive concept;

FIG. 6 is a cross-sectional view of an electronic apparatus according to an embodiment of the present inventive concept;

FIG. 7 is a cross-sectional view of a portion of an electronic apparatus according to an embodiment of the present inventive concept;

FIG. 8 is a cross-sectional view of a portion of an electronic apparatus according to an embodiment of the present inventive concept;

FIG. 9 is a cross-sectional view schematically illustrating a structure of oxide semiconductor layer-electrode according to an embodiment of the present inventive concept;

FIG. 10A is a cross-sectional view schematically illustrating a structure of oxide semiconductor layer-electrode according to Example 1 according to an embodiment of the present inventive concept;

FIG. 10B is a TEM image of a cross-section of a structure of oxide semiconductor layer-electrode according to Example 1 according to an embodiment of the present inventive concept;

FIG. 10C shows the result of measuring a titanium distribution on a cross-section of a structure of oxide semiconductor layer-electrode according to Example 1 according to an embodiment of the present inventive concept;

FIG. 10D shows the result of measuring an oxygen distribution on a cross-section of a structure of oxide semiconductor layer-electrode according to Example 1 according to an embodiment of the present inventive concept;

FIG. 11A is a cross-sectional view schematically illustrating a structure of oxide semiconductor layer-electrode according to Comparative Example 1;

FIG. 11B is a TEM image of a cross-section of a structure of oxide semiconductor layer-electrode according to Comparative Example 1;

FIG. 11C shows the result of measuring a titanium distribution on a cross-section of a structure of oxide semiconductor layer-electrode according to Comparative Example 1;

FIG. 11D shows the result of measuring an oxygen distribution on a cross-section of a structure of oxide semiconductor layer-electrode according to Comparative Example 1;

FIG. 12A is a cross-sectional view schematically illustrating a structure of oxide semiconductor layer-electrode according to Example 2 according to an embodiment of the present inventive concept;

FIG. 12B shows the result of measuring contact resistance between an oxide semiconductor layer and an electrode according to Example 2 according to an embodiment of the present inventive concept;

FIG. 13A is a cross-sectional view schematically illustrating a structure of oxide semiconductor layer-electrode according to Comparative Example 2;

FIG. 13B shows the result of measuring contact resistance between an oxide semiconductor layer and an electrode according to Comparative Example 2; and

FIGS. 14A to 14E are cross-sectional views each illustrating one step of a manufacturing method of a display panel according to embodiments of the present inventive concept.

### DETAILED DESCRIPTION OF EMBODIMENTS

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween. When an element is referred to as being “directly on”, “directly connected to” or “directly coupled to” another element, no intervening elements may be present.

Like reference numerals or symbols refer to like elements throughout. In the drawings, the thickness, ratio, and size of the elements may be exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the present inventive concept. Similarly, a second element, component, region, layer or section could be termed a first element, component, region, layer or section. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, non-limiting embodiments of the present inventive concept are described with reference to the drawings.

The present inventive concept concerns a display panel including a transistor comprising an insertion layer having a dipole layer and an oxygen diffusion prevention layer. The dipole layer may be disposed on an oxide semiconductor layer between the oxide semiconductor layer and the electrode. An oxygen vacancy is formed in the dipole layer which dopes the oxide semiconductor layer. The dipole layer reduces contact resistance between the oxide semiconductor layer and the electrode.

The oxygen diffusion prevention layer may be disposed between the oxide semiconductor layer and the electrode to prevent a phenomenon of Fermi level pinning of metal. The oxygen diffusion prevention layer may be formed on the dipole layer through a process of atomic layer deposition (ALD). In the ALD process, using a precursor material having high reducibility, oxygen vacancy may be formed in the dipole layer.

Since the oxygen diffusion prevention layer is formed on the dipole layer, doping through formation of oxygen vacancy in the dipole layer may prevent oxygen diffusion, so that the formation of a metal oxide layer may be prevented, and a surface defect may be prevented, thereby decreasing the contact resistance.

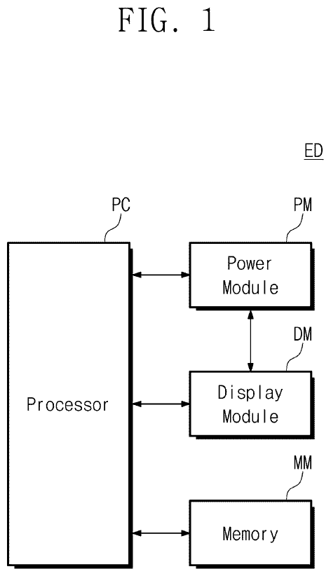

FIG. 1 is a block diagram of an electronic apparatus according to an embodiment of the present inventive concept.

Referring to FIG. 1, an electronic apparatus ED (e.g., an electronic device) according to an embodiment of the present inventive concept may include a display module DM, a processor PC, a memory MM, and a power module PM.

In an embodiment, the processor PC may include at least one of a central processing unit (CPU), an application processor (AP), a graphic processing unit (GPU), a communication processor (CP), an image signal processor (ISP), or a controller.

In the memory MM, data information necessary for operation of the processor PC or the display module DM may be stored. When the processor PC runs an application stored in the memory MM, video data signals and/or input control signals may be transmitted to the display module DM, and the display module DM may process the received signals to output video information (e.g., image display information) through a display screen.

The power module PM may include a power supply module such as a power adapter or a battery device, and a power-converting module that converts power supplied by the power supply module and generate power necessary for operation of the electronic apparatus ED.

At least one among the components of the electronic apparatus ED, previously described, may be included in a display device according to embodiments to be described later. In addition, some of individual modules, included in one functional module, may be included in the display device and others may also be provided separately from the display device. For example, the display device may include the display module DM, and the processor PC, the memory MM, and the power module PM may be provided in the form of a device other than the display device in the electronic apparatus ED.

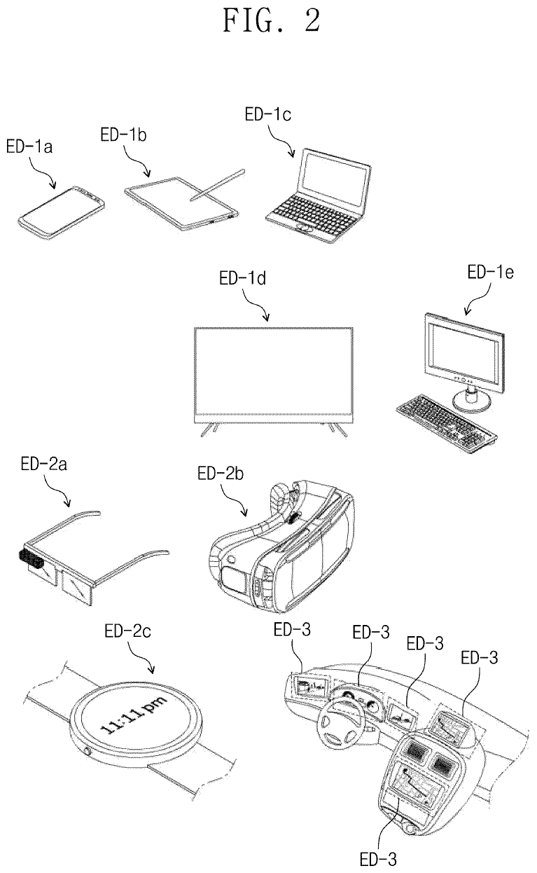

FIG. 2 is a schematic view of various electronic apparatuses (e.g., electronic devices) according to an embodiment of the present inventive concept. Herein, the terms “electronic apparatus” and “electronic device” may be used interchangeably.

Referring to FIG. 2, various electronic apparatuses, applied with a display module according to an embodiment of the present inventive concept, may not only include electronic apparatuses for displaying images such as a smartphone ED-1a, a tablet PC ED-1b, a laptop computer ED-1c, a TV ED-1d, and a desktop monitor ED-1e, but also include wearable electronic apparatuses such as smart glasses ED-2a, a head-mounted display ED-2b, and a smart watch ED-2c, electronic apparatuses for vehicles ED-3 such as a car dashboard, a center fascia, a center information display (CID) disposed on the dashboard, and a room mirror display, and the like. For example, the electronic apparatus may be an outdoor billboard, a personal computer, such as a desktop personal computer, a personal digital assistant, a camera, etc. However, embodiments of the present inventive concept are not necessarily limited thereto and the electronic apparatuses (e.g., electronic devices) that the display device is applied to may include various other small-sized, medium-sized and large-sized display devices.

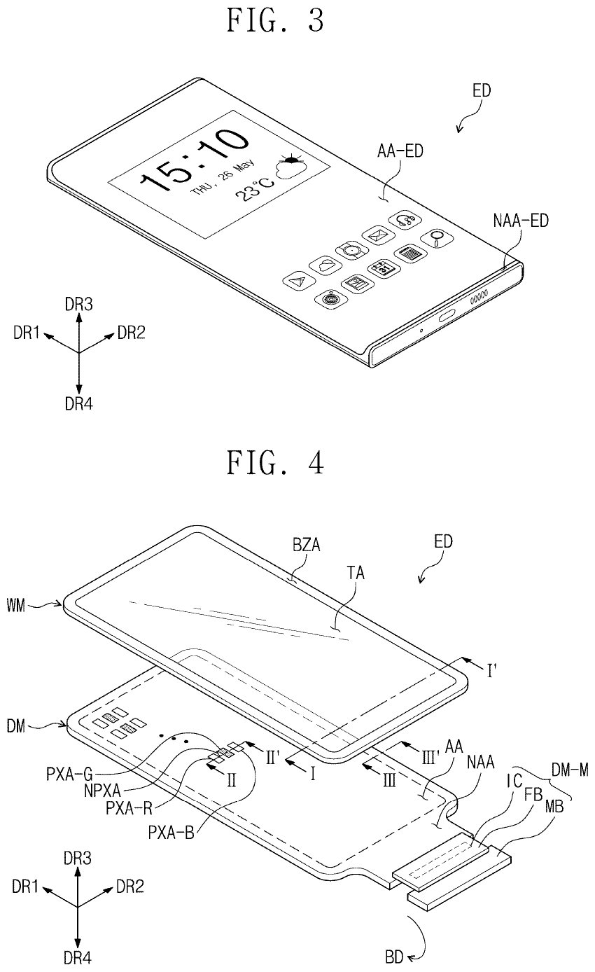

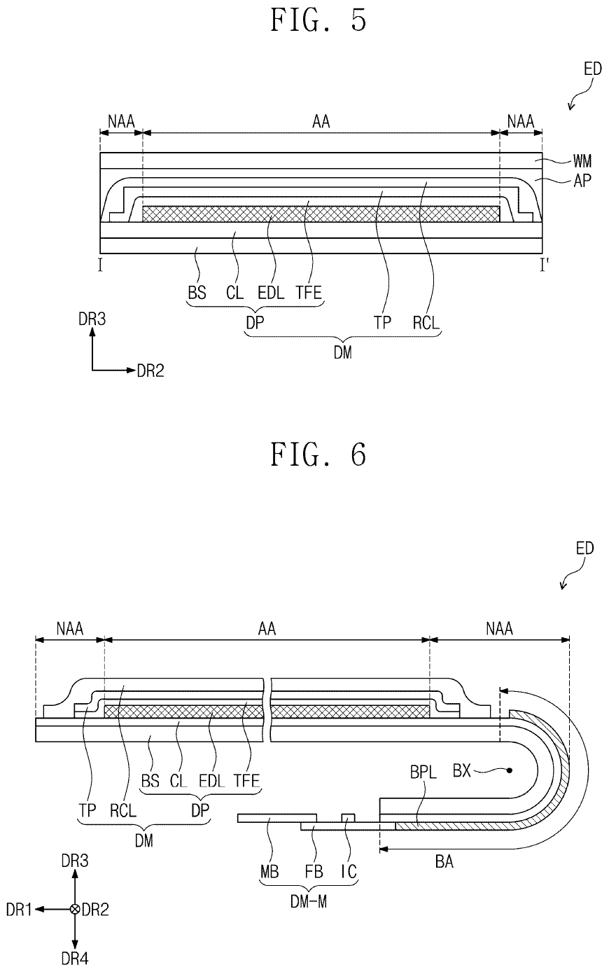

FIG. 3 is a combined perspective view of an electronic apparatus ED according to an embodiment of the present inventive concept. FIG. 4 is an exploded perspective view of an electronic apparatus ED according to an embodiment of the present inventive concept. FIGS. 5 and 6 are cross-sectional views each illustrating an electronic apparatus ED according to an embodiment of the present inventive concept.

The electronic apparatus ED according to an embodiment of the present inventive concept, illustrated in FIGS. 3 to 6, may be activated in response to electrical signals. For example, in an embodiment the electronic apparatus ED may be a mobile phone, a tablet computer, a monitor, a television, a car navigation system, a game console, or a wearable device, but embodiments of the present inventive concept are not necessarily limited thereto. FIG. 3 illustrates that the electronic apparatus ED is a mobile phone.

The electronic apparatus ED according to an embodiment may display at least one moving and/or still image through an active region AA-ED. For example, in an embodiment shown in FIG. 3, the image is software application icons and a clock, temperature and calendar window. However, embodiments of the present inventive concepts are not necessarily limited thereto and the image may be various different subject matter. The active region AA-ED may include a flat surface defined in a first direction DR1 and a second direction DR2. In an embodiment, the active region AA-ED may further include a curved surface bent from at least one side of the flat surface defined in the first direction DR1 and the second direction DR2.

A peripheral region NAA-ED is adjacent to the active region AA-ED (e.g., in a plan view). For example, in an embodiment the peripheral region NAA-ED may surround the active region AA-ED (e.g., in a plan view). Accordingly, a shape of the active region AA-ED may be substantially defined by the peripheral region NAA-ED. However, embodiments of the present inventive concept are not necessarily limited thereto, and the peripheral region NAA-ED may also be disposed adjacent to only one side of the active region AA-ED, or may also be omitted. The electronic apparatus ED according to an embodiment of the present inventive concept may include various shapes of active regions AA-ED (e.g., in a plan view), and is not necessarily limited to any one embodiment.

FIG. 3 illustrates that the electronic apparatus ED according to an embodiment includes two curved surfaces bent from respective sides of the flat surface defined by the first direction DR1 and the second direction DR2. However, the shape of the active region AA-ED is not necessarily limited thereto. For example, the active region AA-ED may include only the flat surface, and the active region AA-ED may further include curved surfaces bent from at least two sides of the flat surface, for example, four curved surfaces respectively bent from four sides of the flat surface.

In FIG. 3 and the following drawings, the first direction DR1 to fourth direction DR4 are illustrated, and directions indicated by the first direction DR1 to fourth direction DR4, described in this specification, may be relative concepts, and may thus be changed to other directions.

In this specification, the first direction DR1 and the second direction DR2 may cross each other, and the third direction DR3 may be a normal direction of a plane defined by the first direction DR1 and the second direction DR2. The fourth direction DR4 is a normal direction of the plane defined by the first direction DR1 and the second direction DR2, and may be a direction toward the opposite direction of the third direction DR3.

A thickness direction of the electronic apparatus ED may be a direction parallel to the third direction DR3 that is the normal direction of the plane defined by the first direction DR1 and the second direction DR2. In this specification, a front surface (e.g., an upper surface) and a rear surface (e.g., a lower surface) of each of members constituting the electronic apparatus ED may be defined on the basis of the third direction DR3.

In this specification, “on a plane” and “in a plan view” may refer to being viewed from a plane parallel to the plane defined by the first direction DR1 and the second direction DR2. In this specification, “overlapping” may refer to overlapping on a plane unless specially defined otherwise.

The electronic apparatus ED according to an embodiment may include a display module DM. The display module DM may be a component that generates an image and detects pressure applied from the outside (e.g., the external environment). The display module DM according to an embodiment includes a display panel DP. The display module DM according to an embodiment may further include a sensor layer TP disposed on the display panel DP, and an optical layer RCL disposed on the sensor layer TP. However, embodiments of the present inventive concept are not necessarily limited thereto, and the sensor layer TP or the optical layer RCL may be omitted in an embodiment.

An active region AA and a peripheral region NAA may be defined in the display module DM. The active region AA may be a region activated in response to electrical signals. The peripheral region NAA may be a region positioned adjacent to at least one side of the active region AA (e.g., in a plan view).

The active region AA may correspond to the active region AA-ED of the electronic apparatus ED illustrated in FIG. 3. The peripheral region NAA may correspond to the peripheral region NAA-ED of the electronic apparatus ED illustrated in FIG. 3.

Referring to FIG. 4, the active region AA may include a plurality of light-emitting regions PXA-R, PXA-G, and PXA-B. For example, the electronic apparatus ED according to an embodiment may include a first light-emitting region PXA-R, a second light-emitting region PXA-G, and a third light-emitting region PXA-B. In an embodiment, the first light-emitting region PXA-R may be a red light-emitting region emitting red light, the second light-emitting region PXA-G may be a green light-emitting region emitting green light, and the third light-emitting region PXA-B may be a blue light-emitting region emitting blue light. However, embodiments of the present inventive concept are not necessarily limited thereto and the number of the light emitting regions and the colors emitted by each of the light emitting regions may vary.

In an embodiment, on a plane, the first to third light-emitting regions PXA-R, PXA-G, and PXA-B may be separated from each other without overlapping each other. For example, a non-light-emitting region NPXA may be disposed between each of the light-emitting regions PXA-R, PXA-G, and PXA-B adjacent to each other.

FIG. 4 illustrates that the light-emitting regions PXA-R, PXA-G, and PXA-B are arranged in a stripe form as an example. For example, in the electronic apparatus ED according to an embodiment illustrated in FIG. 4, the light-emitting regions may be alternately arranged along a second direction DR2 in the order of the first light-emitting region PXA-R, the second light-emitting region PXA-G, and the third light-emitting region PXA-B.

The arrangement form of the light-emitting regions PXA-R, PXA-G, and PXA-B is not necessarily limited to what is illustrated in FIG. 4, and the order in which the first light-emitting region PXA-R, the second light-emitting region PXA-G, and the third light-emitting region PXA-B are arranged may be provided in various combinations, such as according to the display quality characteristics to be required for the electronic apparatus ED. For example, in an embodiment the arrangement form of the light-emitting regions PXA-R, PXA-G, and PXA-B may be a PENTILE™ arrangement form or a Diamond Pixel™ arrangement form.

In an embodiment, the areas of the light-emitting regions PXA-R, PXA-G, and PXA-B that emit light in different wavelength ranges, among the plurality of light-emitting regions PXA-R, PXA-G, and PXA-B, may be different from each other. The area may refer to the area when viewed from the plane defined by the first direction DR1 and the second direction DR2. However, embodiments of the present inventive concept are not necessarily limited thereto, and the light-emitting regions PXA-R, PXA-G, and PXA-B may have the same area as each other in some embodiments. In addition, the area ratio may be variously adjusted according to the display quality characteristics required for the electronic apparatus ED, and the light-emitting regions PXA-R, PXA-G, and PXA-B may be provided in variously different shapes on a plane.

FIG. 4 illustrates that each of the light-emitting regions PXA-R, PXA-G, and PXA-B has a quadrilateral shape on a plane, but embodiments of the present inventive concept are not necessarily limited thereto, and each of the light-emitting regions PXA-R, PXA-G, and PXA-B may have a polygonal shape, a circular shape, or the like on a plane.

The peripheral region NAA may surround the active region AA (e.g., in a plan view). However, embodiments of the present inventive concept are not necessarily limited thereto, and unlike what is illustrated in FIG. 4, etc., a portion of the peripheral region NAA may be omitted. A driving circuit, a driving wire, or the like for driving the active region AA may be disposed in the peripheral region NAA.

Referring to FIG. 6, in an embodiment the peripheral region NAA may include a bending part BA that is bendable with respect to a bending axis BX extending in one direction. For example, in an embodiment the bending axis BX may extend in the second direction DR2. A bending part protection layer BPL may be disposed in the bending part BA. The bending part protection layer BPL may protect a circuit layer CL, etc. disposed in the peripheral region NAA. The bending part protection layer BPL may prevent cracks on the components included in the circuit layer CL, etc. which is exposed in the bending part BA. In an embodiment, the bending part protection layer BPL may include at least one material selected from an acrylate-based polymer, a silicon-based polymer, or an imide-based polymer. However, embodiments of the present inventive concept are not necessarily limited thereto.

Unlike what is illustrated in FIG. 6, the bending part protection layer BPL may be connected to or overlap an edge of the optical layer RCL. In addition, some of the components of the optical layer RCL may also extend to the bending part BA to be provided as the bending part protection layer BPL. In addition, the bending part protection layer BPL may be omitted in an embodiment.

In an embodiment, the display panel DP may be a component that generates an image. In an embodiment, the display panel DP may be a light-emitting display panel, and for example, the display panel DP may be an organic light-emitting display panel, an inorganic light-emitting display panel, a quantum-dot display panel, a micro-LED display panel, or a nano-LED display panel. Hereinafter, the display panel DP according to an embodiment is described as an organic light-emitting display panel for economy of explanation.

FIG. 5 may be a cross-sectional view schematically illustrating a portion corresponding to line I-I′ of FIG. 4. Referring to FIGS. 5 and 6, in an embodiment the display panel DP may include a base layer BS, a circuit layer CL, a light-emitting element layer EDL, and an encapsulation layer TFE.

The base layer BS may be a member that provides a base surface on which the circuit layer CL is disposed. The base layer BS may be a rigid substrate, or a flexible substrate capable of bending, folding, rolling, or the like. In an embodiment, the base layer BS may be a glass substrate, a metal substrate, a polymer substrate, or the like. However, embodiments of the present inventive concept are not necessarily limited thereto, and the base layer BS may be an inorganic layer, an organic layer, or a composite material layer.

The circuit layer CL may be disposed on the base layer BS (e.g., disposed directly thereon in the third direction DR3). The circuit layer CL may include an insulation layer, a semiconductor pattern, a conductive pattern, a signal line, and the like. In an embodiment, an insulation layer, a semiconductor layer, and a conductive layer may be formed on the base layer BS through coating, deposition, etc., and then, the insulation layer, the semiconductor layer, and the conductive layer may be selectively patterned through multiple cycles of a photolithography process and an etching process. After this, the semiconductor pattern, the conductive pattern, and the signal line, included in the circuit layer CL, may be formed.

The light-emitting element layer EDL may be disposed on the circuit layer CL (e.g., disposed directly thereon in the third direction DR3). The light-emitting element layer EDL may include a light-emitting element. For example, the light-emitting element may include an organic light-emitting material, an inorganic light-emitting material, an organic-inorganic light-emitting material, quantum dots, quantum rods, a micro-LED, or a nano-LED.

The encapsulation layer TFE may be disposed on (e.g., disposed directly thereon) the light-emitting element layer EDL. The encapsulation layer TFE may cover the light-emitting element layer EDL. The encapsulation layer TFE may be disposed in the active region AA in which the light-emitting element layer EDL is disposed, and may be disposed extending to the peripheral region NAA in which the light-emitting element layer EDL is not disposed.

In an embodiment, the encapsulation layer TFE may protect the light-emitting element layer EDL from moisture, oxygen, and foreign substance such as dust particles. The encapsulation layer TFE according to an embodiment of the present inventive concept will be described in more detail later.

The sensor layer TP may be disposed on the display panel DP (e.g., in the third direction DR3). The sensor layer TP may detect external input applied from the outside (e.g., the external environment). The external input may be a user's input. The user's input may include various types of external inputs such as a part of the user's body, light, heat, a pen, or pressure. The external input may be a direct touch or a hover.

In an embodiment, the sensor layer TP may be formed on the display panel DP through a continuous process. In this embodiment, the sensor layer TP may be directly disposed on the display panel DP. Here, “directly disposed” may mean that there is no intervening component disposed between the sensor layer TP and the display panel DP. For example, there may be no separate adhesion member disposed between the sensor layer TP and the display panel DP. For example, the sensor layer TP may be directly disposed on the encapsulation layer TFE of the display panel DP (e.g., in the third direction DR3). The sensor layer TP may be bonded to the display panel DP through an adhesion member. The adhesion member may include a general adhesive or sticking agent.

The optical layer RCL may be disposed on sensor layer TP. In an embodiment, the optical layer RCL may be directly disposed on the sensor layer TP. For example, the optical layer RCL may be formed on the sensor layer TP through a continuous process. The optical layer RCL may reduce reflectance for external light incident from the outside of the display module DM. The optical layer RCL may include a polarizing layer or a color filter layer. However, embodiments of the present inventive concept are not necessarily limited thereto and the optical layer RCL may be omitted in an embodiment.

According to an embodiment of the present inventive concept, the sensor layer TP may be omitted. In this embodiment, the optical layer RCL may be directly disposed on the display panel DP. In an embodiment, the position of the sensor layer TP may be switched with that of the optical layer RCL.

The electronic apparatus ED may further include a driving part DM-M electrically connected to the display module DM. The driving part DM-M may be electrically connected to the display panel DP and the sensor layer TP. The driving part DM-M may include a driving chip IC. The driving chip IC may generate or process electrical signals of all kinds, and the driving chip IC may be electrically connected to the display panel DP, the sensor layer TP, and the like, and may thus control the display panel DP and the sensor layer TP.

The driving part DM-M may include a flexible circuit board FB and a driving circuit board MB. The flexible circuit board FB may be electrically connected to the display panel DP and the sensor layer TP on one side, and may be electrically connected to the driving circuit board MB on the other side. The driving chip IC may be disposed on the flexible circuit board FB. In this embodiment, the flexible circuit board FB may also be referred to as a chip on film (CoF). In addition, unlike what is illustrated in the drawing, the driving chip IC may also be disposed on the base layer BS of the display module DM.

FIG. 4 illustrates that the driving part DM-M is connected to one side of the display module DM and unfolded, but as illustrated in FIG. 6, the driving part DM-M may be disposed by being bent BD in a fourth direction DR4 in the electronic apparatus ED according to an embodiment. Referring to FIG. 6, the driving part DM-M may be bent to be disposed overlapping the display panel DP on a plane.

The electronic apparatus ED according to an embodiment may further include a window WM disposed on the display module DM. The window WM may cover the entire outer side of the display module DM. The window WM may be coupled to the display module DM through an adhesion layer AP.

The window WM may have a shape corresponding to the shape of the display module DM. The window WM may include an optically transparent insulating material in the electronic apparatus ED according to an embodiment. The window WM may be a glass substrate or a polymer substrate. For example, the window WM may be a chemically reinforced glass substrate.

The window WM may be divided into a transmission part TA and a bezel part BZA. The transmission part TA may be a portion corresponding to the active region AA of the display module DM, and the bezel part BZA may be a portion corresponding to the peripheral region NAA of the display module DM. The bezel part BZA may define the shape of the transmission part TA. The bezel part BZA may be adjacent to the transmission part TA, and may surround the transmission part TA (e.g., in a plan view). However, embodiments of the present inventive concept are not necessarily limited to what is illustrated in the drawing, and the bezel part BZA may also be disposed adjacent only to one side of the transmission part TA, and one portion may also be omitted.

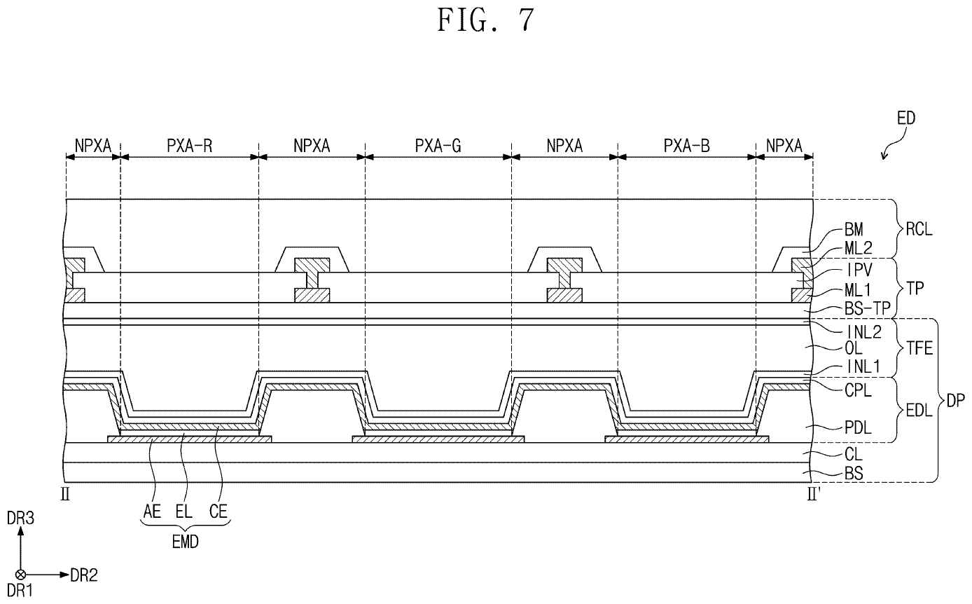

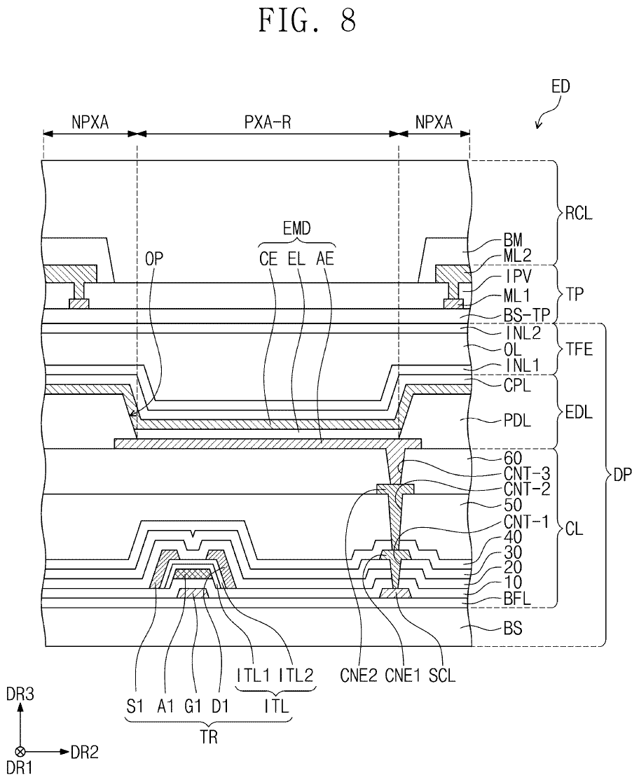

FIGS. 7 and 8 are cross-sectional views each illustrating a portion of an electronic apparatus ED according to an embodiment of the present inventive concept.

FIG. 7 is a cross-sectional view corresponding to line II-II′ of FIG. 4. FIG. 7 illustrates a plurality of light-emitting regions PXA-R, PXA-G, and PXA-B and a non-light-emitting region NPXA according to an embodiment. FIG. 8 illustrates a portion of the electronic apparatus ED illustrated in FIG. 7. FIG. 8 illustrates a first light-emitting region PXA-R and a non-light-emitting region NPXA according to an embodiment.

Referring to FIGS. 7 and 8, the electronic apparatus ED according to an embodiment may include a display panel DP, a sensor layer TP disposed on the display panel DP (e.g., disposed directly thereon in the third direction DR3), and an optical layer RCL disposed on the sensor layer TP (e.g., disposed directly thereon in the third direction DR3).

In an embodiment, the display panel DP may include a base layer BS, a circuit layer CL, a light-emitting element layer EDL, and an encapsulation layer TFE stacked in sequence (e.g., in the third direction DR3).

The base layer BS may be a glass substrate, a metal substrate, a polymer substrate, or the like. However, embodiments of the present inventive concept are not necessarily limited thereto, and the base layer BS may be an inorganic layer, an organic layer, or a composite material layer.

The base layer BS may have a single-layer or multi-layer structure. For example, in an embodiment in which the base layer BS includes a multi-layer structure, the base layer BS may also have a three-layer structure of a synthetic resin layer, an adhesion layer, and a synthetic resin layer. In particular, the synthetic resin layer may include a polyimide-based resin. In addition, the synthetic resin layer may include at least one material selected from an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, “~~-based” resin means including the functional group of “~~”.

The circuit layer CL is disposed on the base layer BS (e.g., disposed directly thereon in the third direction DR3). The circuit layer CL may include a buffer layer BFL. In an embodiment, the buffer layer BFL may include at least one of a silicon oxide layer, a silicon nitride layer, or a silicon oxynitride layer. For example, in the buffer layer BFL, two or more layers selected from the silicon oxide layer, the silicon nitride layer, and the silicon oxynitride layer may be alternately stacked (e.g., in the third direction DR3).

A gate electrode G1 may be disposed on the buffer layer BFL (e.g., disposed directly thereon in the third direction DR3). The gate electrode G1 may be one portion of a metal pattern. The gate electrode G1 may overlap (e.g., in the third direction DR3) an active A1 to be described later. In an embodiment, the gate electrode G1 may include titanium (Ti), silver (Ag), a silver-containing alloy, molybdenum (Mo), a molybdenum-containing alloy, aluminum (Al), an aluminum-containing alloy, aluminum nitride (AlN), tungsten (W), tungsten nitride (WN), copper (Cu), indium tin oxide (ITO), indium zinc oxide (IZO), etc., but is not necessarily limited thereto.

A first insulation layer 10 may be disposed on the buffer layer BFL (e.g., disposed directly thereon in the third direction DR3). The first insulation layer 10 may overlap a plurality of pixels in common, and may cover the gate electrode G1. The first insulation layer 10 may be referred to as a gate insulation film. The first insulation layer 10 may be disposed between the gate electrode G1 and the active A1. The first insulation layer 10 may be an inorganic layer and/or organic layer, and may have a single-layer or multi-layer structure. In an embodiment, the first insulation layer 10 may include at least one compound selected from aluminum oxide, titanium oxide, silicon oxide, silicon nitride, silicon oxynitride, zirconium oxide, or hafnium oxide. In this embodiment, the first insulation layer 10 may be a single-layer silicon oxide layer. Not only the first insulation layer 10 but also an insulation layer of the circuit layer CL to be described later may be an inorganic layer and/or organic layer, and may have a single-layer or multi-layer structure. The inorganic layer may include at least one of the above-described materials, but is not necessarily limited thereto.

An active A1 may be disposed on the first insulation layer 10 (e.g., disposed directly thereon in the third direction DR3). The active A1 may be referred to as a channel. The active A1 may include a metal oxide. The active A1 may include a semiconductor oxide. For example, in an embodiment the active A1 may include at least one compound selected from indium tin zinc oxide (ITZO), indium gallium zinc oxide (IGZO), tin zinc oxide (TZO), aluminum tin zinc oxide (ATZO), zinc oxide (ZnO), or a combination thereof.

A source electrode S1 and a drain electrode D1 may be disposed on the active A1. In an embodiment, the source electrode S1 may be disposed on one end, such as a first side in a plan view, of the active A1. The drain electrode D1 may be disposed on the other end, such as an opposite second side in a plan view, of the active A1. The source electrode S1 and the drain electrode D1 may extend from the active A1 in opposite directions from each other on cross-section. The active A1 may be referred to as a channel.

A transistor TR according to an embodiment of the present inventive concept further includes an insertion layer ITL. The insertion layer ITL may be disposed between the channel A1 and the source electrode S1 and between the channel A1 and the drain electrode D1. Since the insertion layer ITL is disposed between the channel A1 and the source electrode S1, the channel A1 and the source electrode S1 may be separated without being in direct contact with each other. Since the insertion layer ITL is disposed between the channel A1 and the drain electrode D1, the channel A1 and the drain electrode D1 may be separated without being in direct contact with each other.

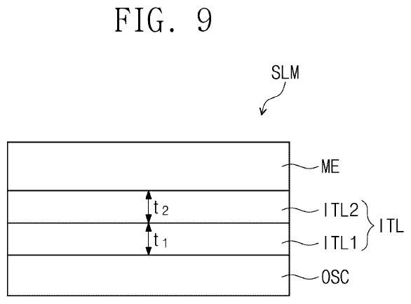

In an embodiment, the insertion layer ITL includes a dipole layer ITL1 and an oxygen diffusion prevention layer ITL2. The dipole layer ITL1 may be disposed on (e.g., disposed directly thereon) the channel A1. The dipole layer ITL1 may be directly disposed on the channel A1 to cover the channel A1. The oxygen diffusion prevention layer ITL2 may be disposed on (e.g., disposed directly thereon) the dipole layer ITL1. The oxygen diffusion prevention layer ITL2 may be directly disposed on the dipole layer ITL1 to cover the dipole layer ITL1. For example, the oxygen diffusion prevention layer ITL2 may be directly disposed between the dipole layer ITL1 and the source electrode S1 and directly between the dipole layer ITL1 and the drain electrode D1. The insertion layer ITL will be described in detail later with reference to FIG. 9.

In an embodiment, pixels may each have an equivalent circuit including a plurality of transistors, one capacitor, and a light-emitting element. However, embodiments of the present inventive concept are not necessarily limited thereto and the equivalent circuit of the pixel may be changed in various forms. FIG. 8 illustrates one transistor TR and one light-emitting element EMD included in a pixel. In an embodiment, the transistor TR may be a thin film transistor.

A second insulation layer 20 may be disposed on the first insulation layer 10, and may cover the source electrode S1 and the drain electrode D1. In an embodiment, the second insulation layer 20 may be an inorganic layer and/or organic layer, and may have a single-layer or multi-layer structure including at least one of a silicon oxide layer, a silicon nitride layer, or a silicon oxynitride layer.

A third insulation layer 30 may be disposed on the second insulation layer 20 (e.g., disposed directly thereon in the third direction DR3), and may have a single-layer or multi-layer structure including at least one of a silicon oxide layer, a silicon nitride layer, or a silicon oxynitride layer.

A first connection electrode CNE1 may be disposed on the third insulation layer 30 (e.g., disposed directly thereon in the third direction DR3). In an embodiment, the first connection electrode CNE1 may be connected to a connection signal line SCL through a contact hole CNT-1 passing through the first, second, and third insulation layers 10, 20, and 30.

A fourth insulation layer 40 may be disposed on the third insulation layer 30 (e.g., disposed directly thereon in the third direction DR3). In an embodiment, the fourth insulation layer 40 may have a single-layer or multi-layer structure including at least one of a silicon oxide layer, a silicon nitride layer, or a silicon oxynitride layer.

A fifth insulation layer 50 may be disposed on the fourth insulation layer 40 (e.g., disposed directly thereon in the third direction DR3). The fifth insulation layer 50 may be an organic layer.

A second connection electrode CNE2 may be disposed on the fifth insulation layer 50 (e.g., disposed directly thereon in the third direction DR3). In an embodiment, the second connection electrode CNE2 may be connected to the first connection electrode CNE1 through a contact hole CNT-2 passing through the fourth insulation layer 40 and the fifth insulation layer 50.

A sixth insulation layer 60 may be disposed on the fifth insulation layer 50 and cover the second connection electrode CNE2. The sixth insulation layer 60 may be an organic layer.

The light-emitting element layer EDL including the light-emitting element EMD may be disposed on the circuit layer CL (e.g., disposed directly thereon in the third direction DR3). The light-emitting element layer EDL may include a pixel-defining film PDL and a light-emitting element EMD comprising a functional layer EL disposed in an opening OP defined in the pixel-defining film PDL.

In an embodiment, the light-emitting element EMD may include a first electrode AE, the functional layer EL, and a second electrode CE. The functional layer EL may include a light-emitting layer. In addition, the functional layer EL may further include a hole transport region and an electron transport region. The first electrode AE may be disposed on the sixth insulation layer 60 (e.g., disposed directly thereon in the third direction DR3). In an embodiment, the first electrode AE may be connected to the second connection electrode CNE2 through a contact hole CNT-3 passing through the sixth insulation layer 60. In an embodiment, the first electrode AE may include at least one selected from Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

In an embodiment in which the first electrode AE is a transmissive electrode, the first electrode AE may include a transparent metal oxide, for example, indium tin oxide (ITO), indium zinc oxide (IZO), zinc oxide (ZnO), indium tin zinc oxide (ITZO), etc.

In an embodiment in which the first electrode AE is a transflective electrode or reflective electrode, the first electrode AE may include Ag, Mg, Cu, Al, Pt, Pd, Au, Ni, Nd, Ir, Cr, Li, Ca, LiF/Ca (e.g., a stacked structure of LiF and Ca), LiF/Al (e.g., a stacked structure of LiF and Al), Mo, Ti, W, or a compound thereof or a mixture thereof (e.g., a mixture of Ag and Mg). Alternatively, the first electrode AE may have a multi-layer structure including a reflective film or a transflective film including the above-mentioned materials, and a transparent conductive film including indium tin oxide (ITO), indium zinc oxide (IZO), zinc oxide (ZnO), indium tin zinc oxide (ITZO), etc. For example, the first electrode AE may have a three-layer structure of ITO/Ag/ITO, but is not necessarily limited thereto.

The pixel-defining film PDL may be disposed on the sixth insulation layer 60 (e.g., disposed directly thereon in the third direction DR3), and may cover a portion of the first electrode AE.

The pixel-defining film PDL may have an opening OP defined therein. The opening OP of the pixel-defining film PDL may expose at least a portion of the first electrode AE. For example, in an embodiment, the pixel-defining film PDL may cover edges of the first electrode AE and expose a central portion of the first electrode AE.

In an embodiment, the light-emitting region PXA-R is defined to correspond to a partial region of the first electrode AE exposed by the opening OP. The non-light-emitting region NPXA may surround the light-emitting region PXA-R (e.g., in a plan view). For example, the pixel-defining film PDL may define the light-emitting regions PXA-R, PXA-G, and PXA-B. The light-emitting regions PXA-R, PXA-G, and PXA-B and the non-light-emitting region NPXA may be distinguished by the pixel-defining film PDL.

In an embodiment, the pixel-defining film PDL may also include a plurality of sub pixel-defining films stacked in a thickness direction.

In an embodiment, the pixel-defining film PDL may include a polymer resin. For example, the pixel-defining film PDL may include a polyacrylate-based resin or a polyimide-based resin. In addition, the pixel-defining film PDL may further include an inorganic material in addition to the polymer resin. The pixel-defining film PDL may include a light-absorbing material, or include a black pigment or black dye. The pixel-defining film PDL including the black pigment or black dye may provide a black pixel-defining film. In an embodiment, carbon black may be used as the black pigment or black dye, but embodiments of the present inventive concept are not necessarily limited thereto.

In addition, the pixel-defining film PDL may include an inorganic material. For example, the pixel-defining film PDL may include silicon nitride, silicon oxide, silicon oxynitride, or the like.

The functional layer EL may be disposed on the first electrode AE (e.g., in the third direction DR3). FIGS. 7 and 8 illustrate that the functional layer EL is provided by being patterned in the opening OP, but embodiments of the present inventive concept are not necessarily limited thereto. In some embodiments, the functional layer EL may be provided overlapping the plurality of light-emitting regions PXA-R, PXA-G, and PXA-B and the non-light-emitting region NPXA.

In an embodiment, the light-emitting layer included in the functional layer EL may be separately provided to each of the light-emitting regions PXA-R, PXA-G, and PXA-B. The light-emitting layer, separated in plurality, may be provided to the light-emitting regions PXA-R, PXA-G, and PXA-B that are separated by the pixel-defining film PDL. In an embodiment, the plurality of light-emitting layers EML may each emit light of at least one color of red color, green color, or blue color. However, embodiments of the present inventive concept are not necessarily limited thereto, and the light-emitting layer may also extend to the plurality of light-emitting regions PXA-R, PXA-G, and PXA-B and the non-light-emitting region NPXA, and provided as a common layer. In this embodiment, the light-emitting layer may provide blue color light, or provide white color light. The light-emitting layer may include an organic light-emitting material, or include a quantum-dot material.

In an embodiment, the hole transport region and the electron transport region may be disposed in the light-emitting regions PXA-R, PXA-G, and PXA-B and the non-light-emitting region NPXA in common. However, embodiments of the present inventive concept are not necessarily limited thereto, and the hole transport region and the electron transport region may be patterned and provided corresponding to the light-emitting regions PXA-R, PXA-G, and PXA-B.

The hole transport region may be disposed between the first electrode AE and the light-emitting layer (e.g., in the third direction DR3). In an embodiment, the hole transport region may include a hole transport layer, and may further include a hole injection layer. The electron transport region may be disposed between the light-emitting layer and the second electrode CE (e.g., in the second direction DR2). In an embodiment, the electron transport region may include an electron transport layer, and may further include an electron injection layer.

In an embodiment, the light-emitting layer may include a fluorescent or phosphorescent material that emits red, green, or blue light. In addition, the light-emitting layer may include a metal organic complex as a light-emitting material. The light-emitting layer may also include quantum dots as a light-emitting material.

The second electrode CE may be disposed on the functional layer EL (e.g., in the third direction DR3). The second electrode CE may have an integrated shape, and extend to the light-emitting regions PXA-R, PXA-G, and PXA-B and the non-light-emitting region NPXA and be disposed as a common layer. In an embodiment, the second electrode CE may include at least one selected from Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

The second electrode CE may be a transmissive electrode, a transflective electrode, or a reflective electrode. In an embodiment in which the second electrode CE is the transmissive electrode, the second electrode CE may include a transparent metal oxide, for example, indium tin oxide (ITO), indium zinc oxide (IZO), zinc oxide (ZnO), indium tin zinc oxide (ITZO), etc.

In an embodiment in which the second electrode CE is a transflective electrode or reflective electrode, the second electrode CE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, or a compound or mixture thereof (e.g., AgMg, AgYb, or MgYb). Alternatively, the second electrode CE may have a multi-layer structure including a reflective film or transflective film including the above-mentioned materials, and a transparent conductive film including indium tin oxide (ITO), indium zinc oxide (IZO), zinc oxide (ZnO), indium tin zinc oxide (ITZO), etc. For example, the second electrode CE may include the above-described metal materials, a combination of two or more metal materials selected from the above-described metal materials, an oxide of the above-described metal materials, or the like.

In an embodiment, the light-emitting element layer EDL may further include a capping layer CPL disposed on the light-emitting element EMD. The capping layer CPL may be disposed on the second electrode CE (e.g., disposed directly thereon in the third direction DR3). The capping layer CPL may include a single-layer or multi-layer structure.

In an embodiment, the capping layer CPL may be an inorganic layer or an organic layer. For example, in an embodiment in which the capping layer CPL includes an inorganic material, the inorganic material may include an alkali metal compound such as LiF, an alkali earth metal compound such as MgF₂, SiON, SiNₓ, SiO_{y}, etc. For example, in an embodiment in which the capping layer CPL includes an organic material, the organic material may contain α-NPD, NPB, TPD, m-MTDATA, Alq₃, CuPc, TPD15(N4,N4,N4′,N4′-tetra(biphenyl-4-yl)biphenyl-4,4′-diamine), TCTA(4,4′,4″-Tris(carbazol-9-yl)triphenylamine), etc., or may contain an epoxy resin, or acrylate such as methacrylate.

The capping layer CPL may function as a buffer layer that protects the light-emitting element EMD, etc. disposed below the capping layer CPL. In an embodiment, the capping layer CPL may have a refractive index greater than or equal to about 1.6. For example, the refractive index of the capping layer CPL may be about 1.9. Since the capping layer CPL has about 1.9 refractive index, the light-emitting element layer EDL may have increased light extraction efficiency, etc.

An upper surface of the light-emitting element layer EDL may be determined by the shapes of the pixel-defining film PDL and the light-emitting element layer EDL. For example, the upper surface of the light-emitting element layer EDL may not be even, and may have a step. The upper surface height of the light-emitting element layer EDL, based on the base layer BS, may vary in the light-emitting regions PXA-R, PXA-G, and PXA-B and the non-light-emitting region NPXA. The step formed due to the uneven upper surface of the light-emitting element layer EDL may be planarized by the encapsulation layer TFE.

The encapsulation layer TFE may be disposed on the light-emitting element layer EDL (e.g., disposed directly thereon in the third direction DR3). In an embodiment, the encapsulation layer TFE includes a first inorganic layer INL1 disposed on the light-emitting element layer EDL, an organic layer OL disposed on the first inorganic layer INL1, and a second inorganic layer INL2 disposed on the organic layer OL.

By including the first inorganic layer INL1 and the second inorganic layer INL2, the encapsulation layer TFE may protect the light-emitting element layer EDL from moisture, oxygen and other contaminants. The encapsulation layer TFE may include the organic layer OL to cover the steps or curves according to the light-emitting element layer EDL. In addition, the encapsulation layer TFE may include the organic layer OL to protect the light-emitting element layer EDL from foreign substance such as dust.

In an embodiment, the first inorganic layer INL1 and the second inorganic layer INL2 may include at least one compound selected from silicon oxide, silicon nitride, silicon oxynitride, titanium oxide, or aluminum oxide. However, the materials of the first inorganic layer INL1 and the second inorganic layer INL2 are not necessarily limited to the above examples.

The organic layer OL may include an acrylate-based compound, an epoxy-based compound, etc. However, the material of the organic layer OL is not necessarily limited to the above examples.

The sensor layer TP may be disposed on the display panel DP (e.g., disposed directly thereon in the third direction DR3). In an embodiment, the sensor layer TP may be directly disposed on the second inorganic layer INL2 (e.g., in the third direction DR3). The sensor layer TP may be referred to as a sensor, an input-sensing layer or an input-sensing panel. The sensor layer TP may include a sensing base layer BS-TP, a first conductive layer ML1, a sensing insulation layer IPV, and a second conductive layer ML2.

The sensing base layer BS-TP may be directly disposed on the display panel DP (e.g., in the third direction DR3). In an embodiment, the sensing base layer BS-TP may be an inorganic layer including at least one compound selected from silicon nitride, silicon oxynitride, or silicon oxide. Alternatively, the sensing base layer BS-TP may also be an organic layer including an epoxy-based resin, an acrylate-based resin, or an imide-based resin. The sensing base layer BS-TP may have a single-layer structure, or may have a structure of multiple layers stacked along a third direction DR3.

The first conductive layer ML1 and the second conductive layer ML2 may each have a single-layer structure, or may have a structure of multiple layers stacked along the third direction DR3. The single-layer conductive layer may include a metal layer or a transparent conductive layer. In an embodiment, the metal layer may include Mo, Ag, Ti, Cu, Al, or an alloy thereof. The transparent conductive layer may include a transparent conductive oxide such as indium tin oxide (ITO), indium zinc oxide (IZO), zinc oxide (ZnO), zinc peroxide (ZnO₂), and indium zinc tin oxide (IZTO). The transparent conductive layer may include a conductive polymer such as PEDOT, a metal nanowire, graphene, etc.

The multi-layer conductive layer may include metal layers. In an embodiment, the metal layers may have a three-layer structure of, for example, Ti/Al/Ti. The multi-layer conductive layer may include at least one metal layer and at least one transparent conductive layer.

The sensing insulation layer IPV may be disposed between the first conductive layer ML1 and the second conductive layer ML2 (e.g., in the third direction DR3). The sensing insulation layer IPV may include an inorganic film. In an embodiment, the inorganic film may include at least one compound selected from aluminum oxide, titanium oxide, silicon oxide, silicon nitride, silicon oxynitride, zirconium oxide, or hafnium oxide.

The sensing insulation layer IPV may include an organic film. In an embodiment, the organic film may include at least one material selected from an acrylate-based resin, a methacrylate-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

The optical layer RCL may be disposed on the sensor layer TP (e.g., disposed directly thereon in the third direction DR3). For example, the optical layer RCL may be formed on the sensor layer TP through a continuous process. However, embodiments of the present inventive concept are not necessarily limited thereto.

The optical layer RCL may also be formed by including a pigment or dye. In an embodiment, the optical layer RCL may include a plurality of filter parts that transmit light of different wavelength ranges. The filter parts that transmit light of different wavelength ranges may be respectively disposed corresponding to the light-emitting regions PXA-R, PXA-G, and PXA-B separated by the non-light-emitting region NPXA.

The optical layer RCL may further include a separation layer BM. A material constituting the separation layer BM is not particularly limited as long as it absorbs light. The separation layer BM may be a layer having black color, and the separation layer BM according to an embodiment may include a black coloring agent. The black coloring agent may include a black dye or black pigment. The black coloring agent may include carbon black, metal such as chrome, or an oxide thereof.

The separation layer BM may cover the second conductive layer ML2 of the sensor layer TP. The separation layer BM may prevent reflection of external light on the second conductive layer ML2.

However, embodiments of the present inventive concept are not necessarily limited thereto, and at least one of the sensor layer TP or the optical layer RCL may also be omitted.

FIG. 9 is a cross-sectional view schematically illustrating a structure of oxide semiconductor layer-electrode according to an embodiment of the present inventive concept. FIG. 9 schematically illustrates some components of the transistor TR of FIG. 8 for the convenience of description. The components of the structure of oxide semiconductor layer-electrode SLM in FIG. 9 may be stacked in the same order as that of the corresponding components of the transistor TR in FIG. 8. In particular, an oxide semiconductor layer OSC of FIG. 9 corresponds to the channel A1 of FIG. 8, and an electrode ME of FIG. 9 corresponds to the source electrode S1 or the drain electrode D1 of FIG. 8. An insertion layer ITL of FIG. 9 is the same as that of FIG. 8. The same description on the channel A1 previously described with reference to FIG. 8 may be applied to the oxide semiconductor layer OSC, and the same description on the source electrode S1 and the drain electrode D1, previously described with reference to FIG. 8, may be applied to the electrode ME. In addition, in an embodiment the oxide semiconductor layer OSC may include an oxide semiconductor, and may include at least one compound selected from, for example, ITZO, IGZO, TZO, ATZO, ZnO, or a combination thereof.

Referring to FIG. 9, the insertion layer ITL is disposed between the oxide semiconductor layer OSC and the electrode ME. The insertion layer ITL may include a dipole layer ITL1 and an oxygen diffusion prevention layer ITL2. Since the insertion layer ITL that includes the dipole layer ITL1 and the oxygen diffusion prevention layer ITL2, is included, the contact resistance between the oxide semiconductor layer OSC and the electrode ME may decrease as compared to a comparative embodiment that does not include such insertion layer ITL between the oxide semiconductor layer OSC and the electrode ME.

The dipole layer ITL1 may be disposed on the oxide semiconductor layer OSC. In an embodiment, the dipole layer ITL1 may be directly disposed on the oxide semiconductor layer OSC. Since the dipole layer ITL1 is disposed between the oxide semiconductor layer OSC and the electrode ME, the contact resistance between the oxide semiconductor layer OSC and the electrode ME may decrease.

In an embodiment, the dipole layer ITL1 may be doped through formation of oxygen vacancy in the dipole layer ITL1, and may thus have the effects of increasing electron movement, and doping the oxide semiconductor layer OSC. Unlike the present inventive concept, in case that the oxygen vacancy is formed in the dipole layer ITL1 through thermal annealing or plasma treatment for forming the dipole layer ITL1, a thick metal oxide layer may be formed between the dipole layer ITL1 and the electrode ME by diffusion of oxygen from the oxide semiconductor layer OSC, thereby significantly increasing the contact resistance, or defect on a surface of the dipole layer ITL1 due to plasma ions may hinder transfer of electrons, thereby increasing the contact resistance. However, according to an embodiment of the present inventive concept, by forming the oxygen diffusion prevention layer ITL2, to be described later, on the dipole layer ITL1, formation of the metal oxide layer and surface defect may be prevented.

The dipole layer ITL1 may include a metal oxide. The dipole layer ITL1 may include a metal oxide that forms oxygen vacancy to dope the oxide semiconductor layer OSC. For example, in an embodiment the dipole layer ITL1 may include at least one compound selected from ITO, ZnO, HfZrO, TiO₂, or a combination thereof. In addition, the dipole layer ITL1 may have a thickness t₁ in a range of about 1 nm to about 10 nm, but is not necessarily limited thereto.

The oxygen diffusion prevention layer ITL2 may be disposed on (e.g., disposed directly thereon) the dipole layer ITL1. The oxygen diffusion prevention layer ITL2 may be directly disposed on the dipole layer ITL1. In a process that the oxygen diffusion prevention layer ITL2 is formed on the dipole layer ITL1, doping through formation of oxygen vacancy in the dipole layer ITL1 may prevent oxygen diffusion, so that the formation of a metal oxide layer may be prevented, and the surface defect may be prevented, thereby decreasing the contact resistance.

In an embodiment, the oxygen diffusion prevention layer ITL2 may be formed on (e.g., formed directly thereon) the dipole layer ITL1 through a process of atomic layer deposition (ALD). In the ALD process, using a precursor material having high reducibility, the dipole layer may be reduced and an oxygen vacancy may be formed in the dipole layer ITL1.

In addition, the oxygen diffusion prevention layer ITL2 may be disposed between the oxide semiconductor layer OSC and the electrode ME to prevent a phenomenon of Fermi level pinning of metal. Unlike an embodiment of the present inventive concept, in a comparative embodiment in which the oxygen diffusion prevention layer ITL2 is not disposed between the oxide semiconductor layer OSC and the electrode ME so that the oxide semiconductor layer OSC is in direct contact with the electrode ME, the electron wave function of metal included in the electrode ME may penetrate into a band gap of a semiconductor included in the oxide semiconductor layer OSC, thereby forming a metal induced gap state (MIGS). In case of the metal induced gap state being formed, the phenomenon of Fermi level pinning, in which the Fermi level of metal is fixed at a charge neutrality level (CNL) of a semiconductor, may occur. If the Fermi level pinning phenomenon occurs, the contact resistance between the oxide semiconductor layer OSC and the electrode ME may increase. Therefore, according to an embodiment of the present inventive concept, by disposing the oxygen diffusion prevention layer ITL2 between the oxide semiconductor layer OSC and the electrode ME, the metal induced gap state, in which the electron wave function of metal penetrates into a band gap of a semiconductor, may be prevented, and the phenomenon of Fermi level pinning may be prevented. The oxygen diffusion prevention layer ITL2 may include a material having a high band gap capable of preventing the phenomenon of Fermi level pinning of metal.

The oxygen diffusion prevention layer ITL2 may include a metal oxide. The oxygen diffusion prevention layer ITL2 may include a metal oxide that blocks oxygen diffusion from the oxide semiconductor layer OSL to the electrode ME. In an embodiment, the oxygen diffusion prevention layer ITL2 may include at least one compound selected from Al₂O₃, TiO₂, ZnO, MgO, HfO₂, or a combination thereof. In addition, the oxygen diffusion prevention layer ITL2 may have a thickness t₂ (e.g., length in the third direction DR3) that allows electron tunneling. If the thickness is larger, the oxygen diffusion prevention layer ITL2 may serve as an insulation layer. For example, in an embodiment the thickness t₂ of the oxygen diffusion prevention layer ITL2 may be less than or equal to about 3 nm. In an embodiment, the thickness t₂ of the oxygen diffusion prevention layer ITL2 may be less than or equal to about 1 nm.

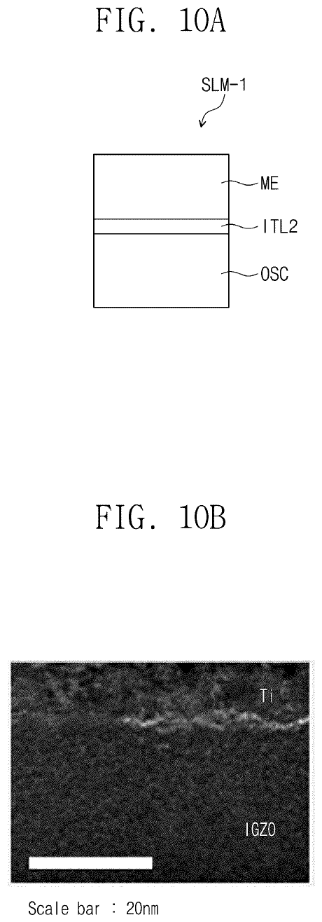

FIG. 10A is a cross-sectional view schematically illustrating a structure of oxide semiconductor layer-electrode according to Example 1. FIG. 10B is a transmission electron microscopy (TEM) image of a cross-section of a structure of oxide semiconductor layer-electrode according to Example 1. FIG. 10C shows the result of measuring a titanium distribution on a cross-section of a structure of oxide semiconductor layer-electrode according to Example 1. FIG. 10D shows the result of measuring an oxygen distribution on a cross-section of a structure of oxide semiconductor layer-electrode according to Example 1.

Referring to FIG. 10A, the structure of oxide semiconductor layer-electrode SLM-1 according to Example 1 has a structure including an oxygen diffusion prevention layer ITL2 between (e.g., directly therebetween) an oxide semiconductor layer OSC and an electrode ME.

Referring to FIG. 10B, the structure of oxide semiconductor layer-electrode SLM-1 according to Example 1 (see FIG. 10A) may have a stacked structure of IGZO/Al₂O₃/Ti as an example. In particular, it is illustrated that, in the structure, the oxide semiconductor layer OSC of FIG. 10A includes IGZO, the electrode ME includes Ti, and the oxygen diffusion prevention layer ITL2 includes Al₂O₃. A bright region between an IGZO layer and a Ti layer shown in the drawing corresponds to a region where Al₂O₃ is disposed. In FIG. 10B and the following drawings, a white bar is illustrated as a scale bar.

Referring to FIG. 10C, it can be seen that, in the structure of oxide semiconductor layer-electrode SLM-1 according to Example 1 (see FIG. 10A), titanium atoms (Ti) are distributed in the electrode ME (see FIG. 10A) region.

Referring to FIG. 10D, it can be seen that, in the structure of oxide semiconductor layer-electrode SLM-1 according to Example 1 (see FIG. 10A), oxygen atoms (O) are distributed only in the oxide semiconductor layer OSC (see FIG. 10A) region and the oxygen diffusion prevention layer ITL2 (see FIG. 10A) region. For example, it can be seen that, since the oxygen diffusion prevention layer ITL2 (see FIG. 10A) was included, oxygen atoms included in the oxide semiconductor layer OSC were prevented from diffusing to the electrode ME region.

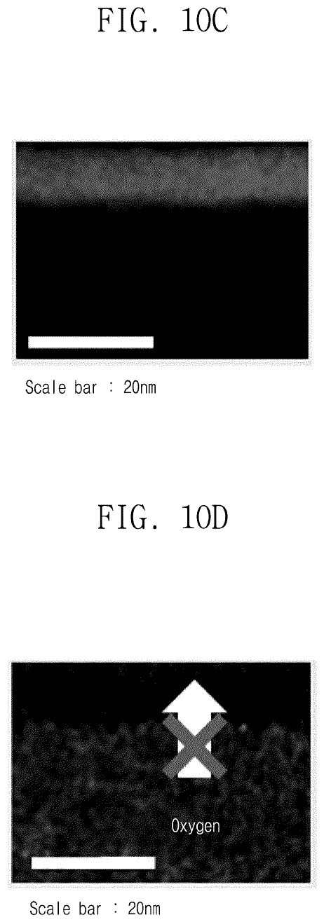

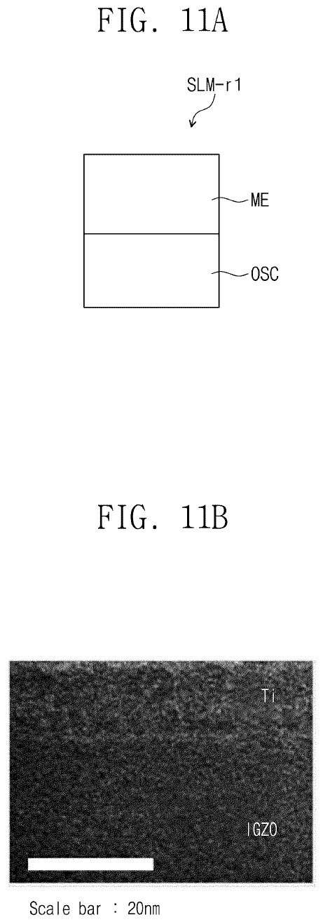

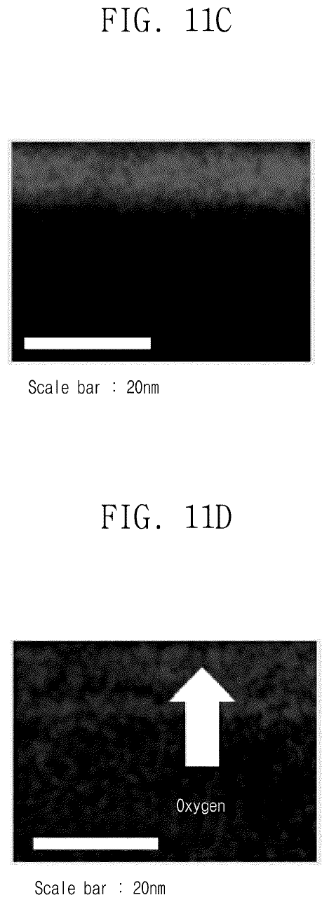

FIG. 11A is a cross-sectional view schematically illustrating a structure of oxide semiconductor layer-electrode according to Comparative Example 1. FIG. 11B is a TEM image of a cross-section of the structure of oxide semiconductor layer-electrode according to Comparative Example 1. FIG. 11C shows the result of measuring a titanium distribution on a cross-section of the structure of oxide semiconductor layer-electrode according to Comparative Example 1. FIG. 11D shows the result of measuring an oxygen distribution on a cross-section of the structure of oxide semiconductor layer-electrode according to the comparative example.

Referring to FIG. 11A, the structure of oxide semiconductor layer-electrode SLM-r1 according to Comparative Example 1 has a structure not including the oxygen diffusion prevention layer ITL2 (see FIG. 10A) between the oxide semiconductor layer OSC and the electrode ME, unlike the structure of oxide semiconductor layer-electrode SML-1 according to Example 1.

Referring to FIG. 11B, the structure of oxide semiconductor layer-electrode SLM-r1 according to Comparative Example 1 (see FIG. 11A) may have a stacked structure of IGZO/Ti as an example. In particular, it is illustrated that, in the structure, the oxide semiconductor layer OSC of FIG. 11A includes IGZO, and the electrode ME includes Ti.

Referring to FIG. 11C, it can be seen that, in the structure of oxide semiconductor layer-electrode SLM-r1 according to Comparative Example 1 (see FIG. 11A), titanium atoms (Ti) are distributed in the electrode ME (see FIG. 10A) region.

Referring to FIG. 11D, it can be seen that, in the structure of oxide semiconductor layer-electrode SLM-r1 according to Comparative Example 1 (see FIG. 11A), oxygen atoms (O) are distributed not only in the oxide semiconductor layer OSC (see FIG. 11A) region but also in the electrode ME (see FIG. 11A) region. For example, unlike Example 1, it can be seen that, since the oxygen diffusion prevention layer ITL2 (see FIG. 10A) was not included, oxygen atoms, included in the oxygen semiconductor layer OSC, diffused to the electrode ME region. Therefore, it can be inferred that a thick metal oxide layer was formed between the oxide semiconductor layer OSC and the electrode ME in the structure of oxide semiconductor layer-electrode SLM-r1 according to Comparative Example 1.

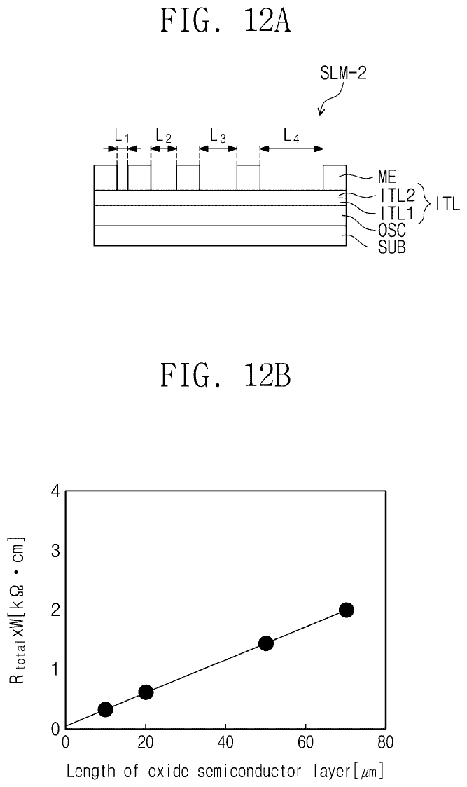

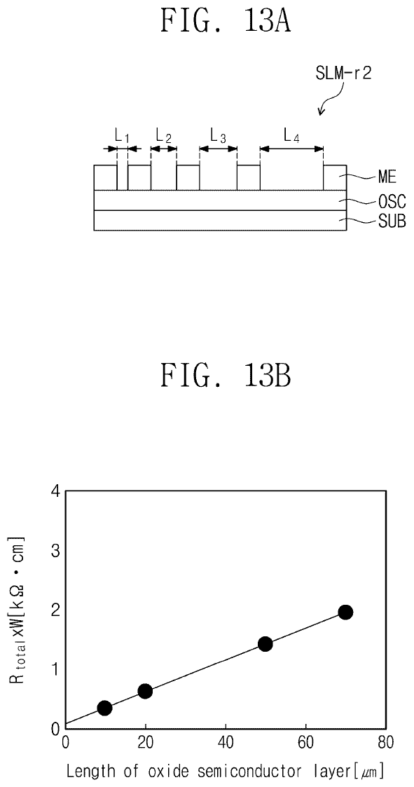

FIG. 12A is a cross-sectional view schematically illustrating a structure of oxide semiconductor layer-electrode according to Example 2. FIG. 12D shows the result of measuring the contact resistance between an oxide semiconductor layer and an electrode according to Example 2. FIG. 13A is a cross-sectional view schematically illustrating a structure of oxide semiconductor layer-electrode according to Comparative Example 2. FIG. 13B shows the result of measuring the contact resistance between an oxide semiconductor layer and an electrode according to Comparative Example 2.

Referring to FIG. 12A, the structure of oxide semiconductor layer-electrode SLM-2 according to Example 2 has a structure including an oxide semiconductor layer OSC and an electrode ME disposed on a substrate SUB and including an insertion layer ITL disposed between the oxide semiconductor layer OSC and the electrode ME (e.g., directly therebetween). The insertion layer ITL includes a dipole layer ITL1 disposed on (e.g., disposed directly thereon) the oxide semiconductor layer OSC and an oxygen diffusion prevention layer ITL2 disposed on (e.g., disposed directly thereon) the dipole layer ITL1. In the structure of oxide semiconductor layer-electrode SLM-2 according to Example 2, the oxide semiconductor layer OSC includes a-IGZO, the dipole layer ITL1 includes ZnO, the oxygen diffusion prevention layer ITL2 includes Al₂O₃, and the electrode ME includes Ti. L₁, L₂, L₃, and L₄ that are distances between the electrodes ME may be about 10 μm, about 20 μm, about 50 μm, and about 70 μm, respectively. The distance between the electrodes ME may be referred to as the length of the oxide semiconductor layer.

Referring to FIG. 12B, to obtain the contact resistance between the oxide semiconductor layer OSC and the electrode ME of the structure of oxide semiconductor layer-electrode SLM-2 according to Example 2 (see FIG. 12A), a value of the total resistance (Rₜₒₜₐₗ) according to the length of the oxide semiconductor layer×the width (W) of the oxide semiconductor layer was measured. The contact resistance may be derived by using a transfer line method (TLM). The total resistance may be represented by Equation 1 below.

$${R}_{total} = {R}_{ch} + 2 {R}_{c} = \frac{{R}_{sheet}}{W} L + 2 {R}_{c} \qquad [ Equation 1 ]$$

In Equation 1 above, Rₜₒₜₐₗ is a total resistance of the structure of oxide semiconductor layer-electrode SLM-2 (see FIG. 12A), R_{ch} is a resistance of the oxide semiconductor layer, R_{c} is a contact resistance between the oxide semiconductor layer OSL and the electrode ME, Rₛₕₑₑₜ is a sheet resistance of the oxide semiconductor layer, W is a width of the oxide semiconductor layer, and L is a length of the oxide semiconductor layer.

Here, when the width (W) of the oxide semiconductor layer is fixed, and the electrodes ME differently spaced are each selected so that the length (L) of the oxide semiconductor layer varies, and the resistance R_{ch} of the oxide semiconductor layer changes, but the contact resistance R_{c} is constant. For example, like in FIG. 12B, when the length of the oxide semiconductor layer represents the X axis, the value of the total resistance Rₜₒₜₐₗ×the width (W) of the oxide semiconductor layer represents the Y axis, the contact resistance R_{c} may be derived from the Y-intercept value. Accordingly, the contact resistance R_{c} according to Example 2 was derived as about 44Ω.

Referring to FIG. 13A, a structure of oxide semiconductor layer-electrode SLM-r₂ according to Comparative Example 2 has a structure including an oxide semiconductor layer OSC and an electrode ME disposed on a substrate SUB. In the structure of oxide semiconductor layer-electrode SLM-r2 according to Comparative Example 2, the oxide semiconductor layer OSC includes a-IGZO, and the electrode ME includes Ti. L₁, L₂, L₃, and L₄ that are distances between the electrodes ME may be about 10 μm, about 20 μm, about 50 μm, and about 70 μm, respectively. The distance between the electrodes ME may be referred to as the length of the oxide semiconductor layer.

Referring to FIG. 13B, to obtain the contact resistance between the oxide semiconductor layer OSC and the electrode ME of the structure of oxide semiconductor layer-electrode SLM-r2 according to Comparative Example 2 (see FIG. 13A), a value of the total resistance (Rₜₒₜₐₗ) according to the length of the oxide semiconductor layer×the width (W) of the oxide semiconductor layer was measured. The contact resistance may be derived by the method previously described for Example 2. The contact resistance R_{c} according to Comparative Example 2 was derived as about 156Ω.

Referring to FIGS. 12A to 13B, it can be seen that the contact resistance according to Example 2, where the insertion layer ITL was disposed between the oxide semiconductor layer OSL and the electrode ME, was reduced by about 72% compared to the contact resistance according to Comparative Example 2 where the oxide semiconductor layer OSL and the electrode ME were directly in direct contact with each other without the insertion layer ITL being disposed therebetween.

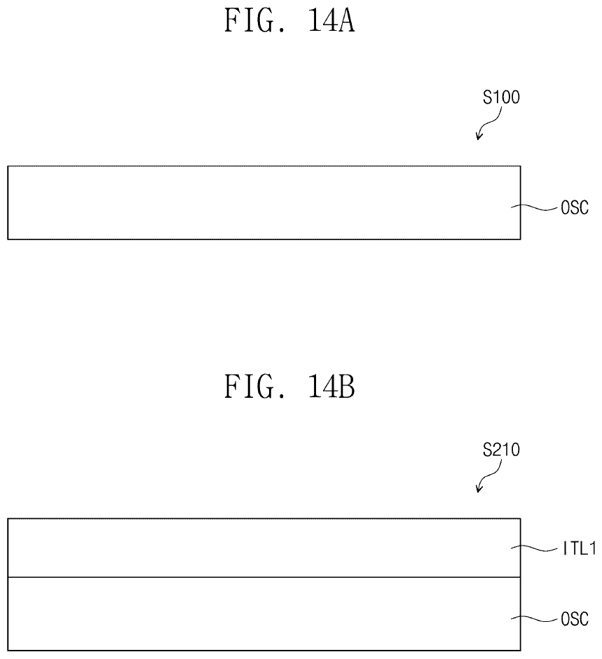

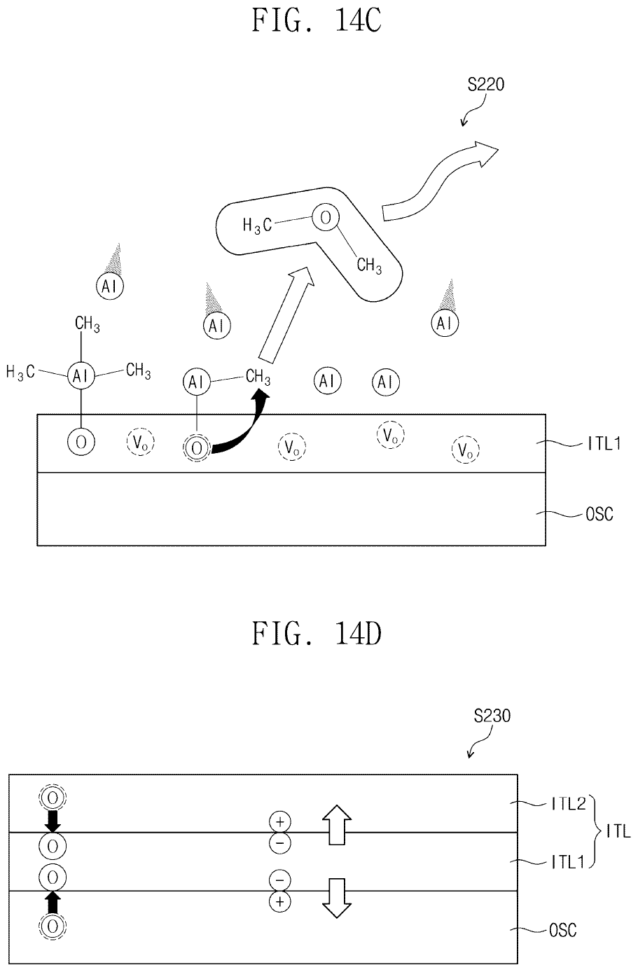

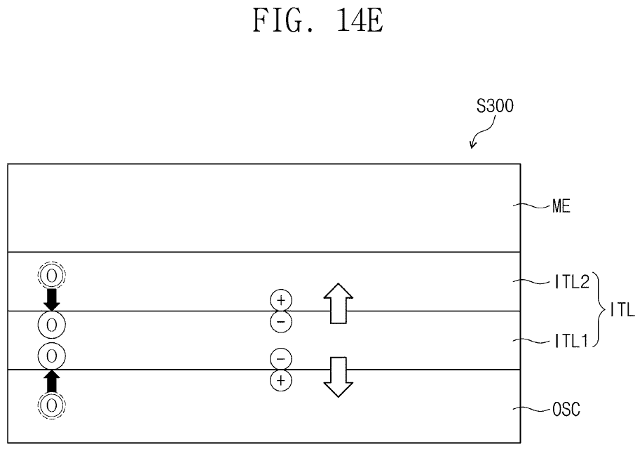

FIGS. 14A to 14E are cross-sectional views each illustrating one step of a manufacturing method of a display panel according to embodiments of the present inventive concept.

The manufacturing method of a display panel according to an embodiment may include forming the channel A1 (see FIG. 8) in step S100, forming an insertion layer on the channel A1 (see FIG. 8) in steps S210, S220, and S230, and forming the source electrode S1 (see FIG. 8) and the drain electrode ITL (see FIG. 8) on the insertion layer ITL in step S300.

For the convenience of description, FIGS. 14A to 14E illustrate the oxide semiconductor layer OSL corresponding to the channel A1 of FIG. 8, and the electrode ME corresponding to the source electrode S1 or the drain electrode D1 of FIG. 8. In addition, it is described as an example that the oxide semiconductor layer OSL includes IGZO, the dipole layer ITL1 includes ZnO, the oxygen diffusion prevention layer ITL2 includes Al₂O₃, and the electrode includes Ti.

Referring to FIG. 14A, the manufacturing method of a display panel according to an embodiment may include the forming of the channel A1 (see FIG. 8) in step S100. The forming of the channel A1 (see FIG. 8) in step S100 may be a step of forming the oxide semiconductor layer OSL. For example, in an embodiment the oxide semiconductor layer OSL may be formed as an IGZO layer.

Referring to FIGS. 14B to 14D, the manufacturing method of a display panel according to an embodiment may include the forming of the insertion layer ITL in steps S210, S220, and S230. The forming of the insertion layer ITL in steps S210, S220, and S230 may include forming a dipole layer ITL1 in step S210 and forming an oxygen diffusion prevention layer ITL2 in steps S220 and S230. In an embodiment, the dipole layer ITL1 and the oxygen diffusion prevention layer ITL2 may each be formed through an ALD process.

FIG. 14B schematically illustrates the forming of the dipole layer ITL1 in step S210. The dipole layer ITL1 may be formed on the oxide semiconductor layer OSL through the ALD process. For example, in an embodiment the dipole layer ITL1 may be formed as a ZnO layer.

FIGS. 14C and 14D schematically illustrate the forming of the oxygen diffusion prevention layer ITL2 in steps S220 and S230. The oxygen diffusion prevention layer ITL2 may be formed on the dipole layer ITL1 through the ALD process. For example, in an embodiment the oxygen diffusion prevention layer ITL2 may be formed as an Al₂O₃ layer. In the oxygen diffusion prevention layer ITL2, doping may occur through formation of oxygen vacancy in the dipole layer ITL1 using a metal precursor having a high reducibility. For example, in an embodiment trimethyl aluminum (TMA) may be used as an aluminum precursor to form oxygen vacancy in the ZnO layer. FIG. 14D illustrates a state in which the oxygen diffusion prevention layer ITL2 is formed and a dipole is formed on the dipole layer ITL1. Accordingly, the oxide semiconductor layer OSL may have the doping effect.

Referring to FIG. 14E, the manufacturing method of a display panel according to an embodiment may include the forming of the source electrode S1 (see FIG. 8) and the drain electrode D1 (see FIG. 8) on the insertion layer ITL in step S300. The forming of the source electrode S1 (see FIG. 8) and the drain electrode D1 (see FIG. 8) in step S300 may be a step of forming the electrode ME. For example, the electrode ME may be formed as a Ti layer.

According to what is previously described, a thin film transistor included in a display panel according to the present inventive concept may have reduced contact resistance.

In addition, by including the thin film transistor with reduced contact resistance, an electronic apparatus according to an embodiment of the present inventive concept may have increased reliability.

Furthermore, a manufacturing method for a display panel according to an embodiment of the present inventive concept may provide the display panel including the thin film transistor with reduced contact resistance.

In the above, description has been made with reference to non-limiting embodiments of the present inventive concept and those skilled or of ordinary skill in the art may understand that various modifications and changes may be made to the present inventive concept insofar as such modifications and changes do not depart from the spirit and technical scope of the present inventive concept.

What is claimed is:

1. A display panel, comprising:
a base layer;
a light-emitting element layer disposed on the base layer and including a light-emitting element; and
a circuit layer disposed on the base layer and including a thin film transistor electrically connected to the light-emitting element,
wherein the thin film transistor comprises:
a gate electrode,
a channel overlapping the gate electrode and including an oxide semiconductor,
a source electrode disposed on a first end of the channel,
a drain electrode disposed on an opposite second end of the channel, and
an insertion layer disposed between the channel and the source electrode and between the channel and the drain electrode, and
the insertion layer comprises a dipole layer disposed on the channel, and an oxygen diffusion prevention layer disposed on the dipole layer.

2. The display panel of claim 1, wherein:
the dipole layer is directly disposed on the channel; and
the dipole layer comprises a metal oxide that forms oxygen vacancy in the dipole layer to dope the channel.

3. The display panel of claim 1, wherein:
the oxygen diffusion prevention layer is directly disposed between the dipole layer and the source electrode, and between the dipole layer and the drain electrode; and
the oxygen diffusion prevention layer comprises a metal oxide that blocks oxygen diffusion from the channel to the source electrode and the drain electrode.

4. The display panel of claim 1, wherein the oxygen diffusion prevention layer has a thickness that allows electron tunneling.

5. The display panel of claim 1, wherein the oxygen diffusion prevention layer has a thickness in a range of less than or equal to about 3 nm.

6. The display panel of claim 1, wherein the oxygen diffusion prevention layer has a thickness in a range of less than or equal to about 1 nm.

7. The display panel of claim 1, wherein the oxygen diffusion prevention layer comprises at least one compound selected from Al₂O₃, TiO₂, ZnO, MgO, HfO₂, or a combination thereof.

8. The display panel of claim 1, wherein the dipole layer comprises at least one compound selected from ITO, ZnO, HfZrO, TiO₂, or a combination thereof.

9. The display panel of claim 1, wherein the channel comprises at least one compound selected from ITZO, IGZO, TZO, ATZO, ZnO, or a combination thereof.

10. The display panel of claim 1, wherein the circuit layer further comprises a gate insulation film disposed between the gate electrode and the channel.

11. An electronic device comprising:
a display module including a base layer, a light-emitting element layer disposed on the base layer and comprising a light-emitting element, and a circuit layer disposed on the base layer and comprising a thin film transistor electrically connected to the light-emitting element; and
a window disposed on the display module,
wherein the thin film transistor comprises:
a gate electrode,
a channel overlapping the gate electrode and including an oxide semiconductor,
a source electrode disposed on a first end of the channel,
a drain electrode disposed on an opposite second end of the channel, and
an insertion layer disposed between the channel and the source electrode and between the channel and the drain electrode, and
the insertion layer comprises a dipole layer disposed on the channel, and an oxygen diffusion prevention layer disposed on the dipole layer.

12. The electronic device of claim 11, wherein the dipole layer comprises a metal oxide that forms oxygen vacancy in the dipole layer to dope the channel.

13. The electronic device of claim 11, wherein the oxygen diffusion prevention layer comprises a metal oxide that blocks oxygen diffusion from the channel to the source electrode and the drain electrode.

14. The electronic device of claim 11, further comprising at least one of a processor, a memory, or a power module.

15. The electronic device of claim 11, wherein the electronic device is a television, a monitor, an outdoor billboard, a personal computer, a laptop computer, a personal digital assistant, a car dashboard, a center fascia, a navigation system, a room mirror display, a game console, a smartphone, a tablet computer, a smart watch, smart glasses, a head-mounted display, or a camera.

16. A method of manufacturing a display panel, comprising:
forming a channel including an oxide semiconductor;
forming an insertion layer on the channel; and
forming a source electrode and a drain electrode on the insertion layer, wherein the insertion layer is disposed between the source electrode and the channel and between the drain electrode and the channel,
wherein the forming of the insertion layer comprises forming a dipole layer on the channel, and forming an oxygen diffusion prevention layer while reducing the dipole layer using a metal precursor with reducibility.

17. The method of claim 16, wherein the insertion layer is formed through an atomic layer deposition (ALD) process.

18. The method of claim 16, wherein the dipole layer comprises a metal oxide that forms oxygen vacancy in the dipole layer to dope the channel.

19. The method of claim 16, wherein the oxygen diffusion prevention layer comprises a metal oxide that blocks oxygen diffusion from the channel to the source electrode and the drain electrode.

20. The method of claim 16, wherein the oxygen diffusion prevention layer has a thickness that allows electron tunneling.
